(19) United States
(12) Patent Application Publication
(10) Pub. No.: US 2016/0017484 A1
(43) Pub. Date: Jan. 21, 2016

(54) CARBON FILM FORMATION METHOD, AND CARBON FILM

(71) Applicants: TOKYO ELECTRON LIMITED, Minato-ku, Tokyo (JP); TOHOKU UNIVERSITY, Sendai-shi, Miyagi (JP)

(72) Inventors: Yoshiyuki KIKUCHI, Miyagi (JP); Seiji SAMUKAWA, Miyagi (JP)

(73) Assignees: TOHOKU UNIVERSITY, Miyagi (JP); TOKYO ELECTRON LIMITED, Tokyo (JP)

(21) Appl. No.: 14/770,656

(22) PCT Filed: Jan. 30, 2014
(86) PCT No.: PCT/JP2014/052150

§ 371 Date: Aug. 26, 2015

(30) Foreign Application Priority Data
Feb. 28, 2013 (JP) 2013-038911

(51) Int. Cl. C23C 16/26; C23C 16/48; C23C 16/511

(52) U.S. Cl. CPC C23C 16/26; C23C 16/511; C23C 16/48

(57) ABSTRACT

A carbon film formation method according to an exemplary embodiment includes supplying an aromatic hydrocarbon gas having a methyl group into a processing chamber that accommodates a workpiece; generating plasma of a noble gas in a plasma generating chamber that is isolated from the processing chamber by a shielding unit; supplying particles in the plasma into the processing chamber through an opening in the shielding unit; and irradiating the particles to the aromatic hydrocarbon gas to form a carbon film having a π-conjugated ring structure or a π-conjugated chain structure on the workpiece.

### TECHNICAL FIELD

Exemplary embodiments of the present disclosure relate to a carbon film formation method, and a carbon film.

### BACKGROUND

A conductive carbon film has been used, for example, for an electrode of a biosensor. The biosensor is a device using a bio-originated molecule recognition mechanism. The biosensor includes a bio-originated detection unit that responds to a specific chemical substance and a transducer that converts a detection signal from the detection unit into an electrochemical signal such as current or voltage. As for the detection electrode of the transducer, there has been an attempt to use a carbon film that is highly biocompatible and is low-priced. Here, since the signal from the bio-originated detection unit is weak, the carbon film used as the detection electrode is required to have a high conductivity. Conventionally, there has been known a method in which a carbon paste is printed on a substrate so as to form a carbon film at a low cost. However, since the carbon paste is printed under an atmospheric pressure, the purity of the carbon film is inevitably reduced. When such a low-purity carbon film is used as the detection electrode, the accuracy of the biosensor may be lowered.

As a method of forming a high-conductive and high-purity carbon film, a carbon film formation method using CVD is conventionally known. For example, Patent Document 1 discloses a method of forming a boron-doped diamond film on a substrate, including supplying a raw material gas containing a carbon source and a boron source into a decompressed container and diffusing, as a reactive product, the raw material gas heated by disposing a hot filament heated to about 2,000° C. to 2,200° C. above the substrate. In the method, the diamond film is grown at a processing temperature of 700° C. to 1,000° C.

Further, Patent Document 2 discloses a method of forming a graphene on a substrate using plasma CVD. In the method, the substrate is subjected to a plasma processing with plasma generated from a mixed gas containing a hydrocarbon gas, plasma generated from a gas containing a hydrocarbon gas is irradiated to the substrate so as to prepare the graphene, and the graphene is exposed to plasma generated from a noble gas so as to improve the quality of the graphene. In the method, the graphene is formed at a processing temperature of 200° C. or higher.

### PRIOR ART DOCUMENT

### Patent Document

Patent Document 1: Japanese Patent Laid-Open Publication No. 2005-54264
Patent Document 2: Japanese Patent Laid-Open Publication No. 2010-212619

### SUMMARY OF THE INVENTION

### Problems to be Solved

Since a high-temperature processing causes the biosensor not to function, it is required to form the detection electrode of the biosensor at a low temperature. In the methods disclosed in Patent Documents 1 and 2, it is necessary to perform a high-temperature processing on the carbon film in order to make the carbon film conductive. Therefore, it is difficult to apply the methods disclosed in Patent Documents 1 and 2 to the formation of an electrode of a device requiring a low-temperature processing, such as, for example, the biosensor. Further, in the method disclosed in Patent Document 2, the growth temperature of the carbon film is lower than that in a general formation method of the carbon film. However, considering the application to the biosensor, the growth temperature is not sufficiently low.

Thus, in the related art, there are demands for a carbon film formation method capable of forming a carbon film, which is excellent in conductivity, at a low temperature, and a carbon film formed by the method.

### Means to Solve the Problems

According to an aspect, the present disclosure provides a carbon film formation method including supplying an aromatic hydrocarbon gas having a methyl group into a processing chamber that accommodates a workpiece; generating plasma of a noble gas in a plasma generating chamber that is isolated from the processing chamber by a shielding unit; supplying particles in the plasma into the processing chamber through an opening in the shielding unit; and irradiating the particles to the aromatic hydrocarbon gas to form a carbon film having a π-conjugated ring structure or a π-conjugated chain structure on the workpiece. In an exemplary embodiment, the aromatic hydrocarbon gas may be a toluene gas.

In the carbon film formation method, the particles in the plasma are irradiated to the aromatic hydrocarbon gas to form a carbon film having a π-conjugated ring structure or a π-conjugated chain structure on the workpiece. Since the carbon film has a π-conjugated structure, the carbon film has a high carrier mobility and a high conductivity. In the method, the particles are irradiated to cleave the aromatic hydrocarbon gas and form the carbon film while maintaining the molecular structure. Therefore, the carbon film may be formed at a low temperature.

In an exemplary embodiment, when the carbon film is formed, a pressure in the plasma generating chamber may be set to 70 Pa or more and the pressure in the plasma generating chamber is set to be twice a pressure in the processing chamber or less.

The present inventors have found that a carbon film having an excellent conductivity may be formed by setting the pressure in the plasma generating chamber to 70 Pa or more and setting the pressure in the plasma generating chamber to be twice the pressure in the processing chamber or less. When the pressures in the plasma generating chamber and the processing chamber are set in the above-described range, the particles passing through the shielding unit may have an energy capable of suppressing excessive dissociation of the toluene. The particles are irradiated to the toluene, which is then cleaved to generate many C═C—C═C* groups. Here, “C” represents a carbon atom, “—” represents a single bond, and “═” represents a double bond. The C═C—C═C* groups are radically polymerized to form a carbon film having a π-conjugated ring structure. As such, according to the method of the present disclosure, a carbon film having an excellent conductivity may be formed.

In an exemplary embodiment, when the carbon film is formed, a temperature of a placing table on which the workpiece is placed may be set to 100° C. or less. According to the exemplary embodiment, deterioration of the device caused by heat treatment may be suppressed. Further, according to the exemplary embodiment, radicals derived from the toluene may be collected on the workpiece, and the absorption probability of the radicals to the workpiece may be enhanced.

In an exemplary embodiment, the shielding unit may have a shielding property against ultraviolet rays. According to the exemplary embodiment, a defect causing a carrier trap may be suppressed from occurring in the carbon film.

In an exemplary embodiment, the plasma may be generated by supplying microwaves into the plasma generating chamber. Further, the microwaves may be supplied from a radial line slot antenna.

In an exemplary embodiment, when the carbon film is formed, the processing chamber may be supplied with a dopant selected from any one of iodine, bromine, nitrogen, and boron. According to the exemplary embodiment, the carrier concentration in the carbon film may be increased.

A carbon film according to an aspect of the present disclosure is a carbon film formed by the above-described carbon film formation method. As described above, the carbon film has a high conductivity and is formed at a low temperature.

### Effect of the Invention

According to the carbon film formation method of the present disclosure, a carbon film having an excellent conductivity may be formed at a low temperature.

### BRIEF DESCRIPTION OF THE DRAWINGS

FIG. 1 is a schematic cross-sectional view illustrating a film forming apparatus according to an exemplary embodiment.

FIG. 2 is a plan view illustrating an exemplary slot plate.

FIG. 3 is a view for explaining a carbon film formation method according to the exemplary embodiment.

FIG. 4 is a view illustrating a structural formula of toluene.

FIG. 5 is a view illustrating an exemplary carbon film according to the exemplary embodiment.

FIG. 6 is a view illustrating an infrared absorption spectrum of the carbon film.

FIG. 7 is a view illustrating a relationship between a potential and a current value in a potential sweep of the carbon film.

FIG. 8 is a view illustrating another exemplary carbon film according to the exemplary embodiment.

FIG. 9 is a view illustrating still another exemplary carbon film according to the exemplary embodiment.

### DETAILED DESCRIPTION TO EXECUTE THE INVENTION

Hereinafter, various exemplary embodiments of the present disclosure will be described in detail with reference to the accompanying drawings. Further, the same reference numerals will be given to the same or corresponding portions in respective drawings.

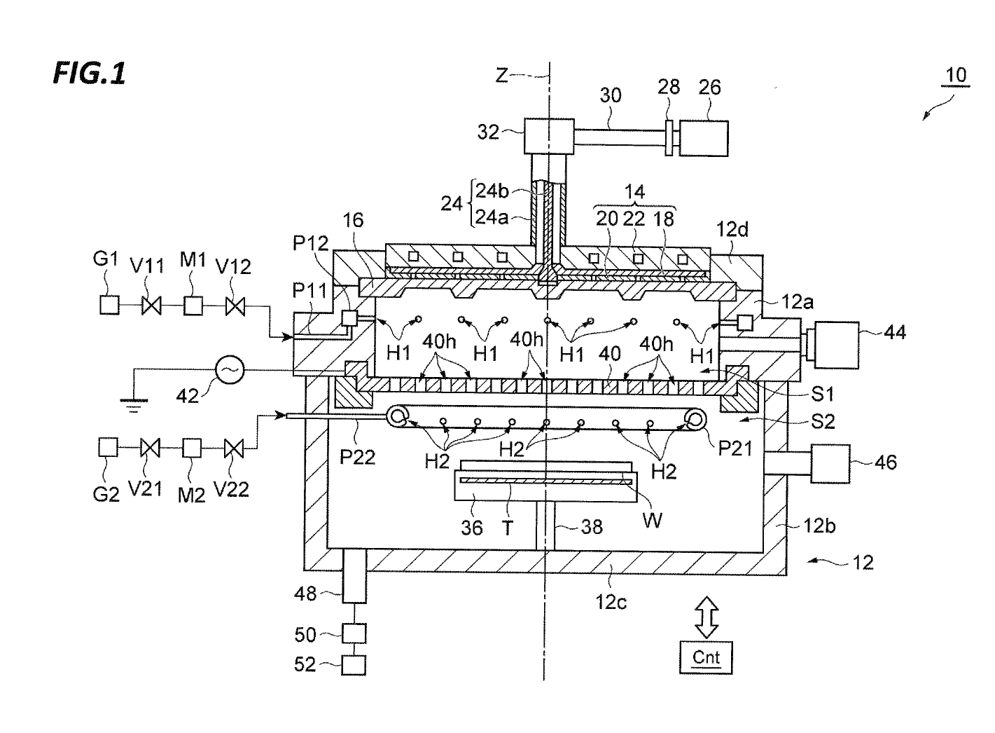

First, descriptions will be made on a film forming apparatus which may be used for a carbon film formation method according to an exemplary embodiment. FIG. 1 is a schematic cross-sectional view illustrating a film forming apparatus according to an exemplary embodiment. The film forming apparatus 10 illustrated in FIG. 1 includes a processing container 12. The processing container 12 is a substantially cylindrical container that extends in a direction where an axis Z extends (hereinafter, referred to as an “axis Z direction”), and defines a space S therein. The space S includes a plasma generating chamber S1 and a processing chamber S2 provided below the plasma generating chamber S1.

In the exemplary embodiment, the processing container 12 may include a first sidewall 12a, a second sidewall 12b, a bottom portion 12c, and an upper portion 12d. The first sidewall 12a has a substantially cylindrical shape that extends in the axis Z direction, and defines the plasma generating chamber S1.

The first sidewall 12a includes gas lines P11 and P12 formed therein. The gas line P11 extends from the outer surface of the first sidewall 12a and is connected to the gas line P12. The gas line P12 extends substantially annularly around the axis Z in the first sidewall 12a. The gas line P12 is connected with a plurality of injection ports H1 that injects a gas to the plasma generating chamber S1.

Further, the gas line P11 is connected with a gas source G1 via a valve V11, a mass flow controller M1, and a valve V12. The gas source G1 is a noble gas source. In an exemplary embodiment, the gas source G1 is an Ar gas source. The gas source G1, the valve V11, the mass flow controller M1, the valve V12, the gas lines P11 and P12, and the injection ports H1 constitute a noble gas supply system. The noble gas supply system controls the flow rate of the noble gas from the gas source G1 in the mass flow controller M1, and supplies the noble gas into the plasma generating chamber S1 at the controlled flow rate.

Further, the upper portion 12d is provided at the upper end of the first sidewall 12a. The upper portion 12d has an opening formed therein, and an antenna 14 is provided inside the opening. Further, a dielectric window 16 is provided just below the antenna 14 to seal the plasma generating chamber S1.

The antenna 14 supplies microwaves into the plasma generating chamber S1 through the dielectric window 16. In an exemplary embodiment, the antenna 14 is a radial line slot antenna. The antenna 14 includes a dielectric plate 18 and a slot plate 20. The dielectric plate 18 shortens the wavelength of the microwaves and is substantially disc-shaped. The dielectric plate 18 is made of, for example, quartz or alumina. The dielectric plate 18 is sandwiched between the slot plate 20 and a metal-made bottom surface of a cooling jacket 22. Therefore, the antenna 14 may be configured by the dielectric plate 18, the slot plate 20, and the bottom surface of the cooling jacket 22.

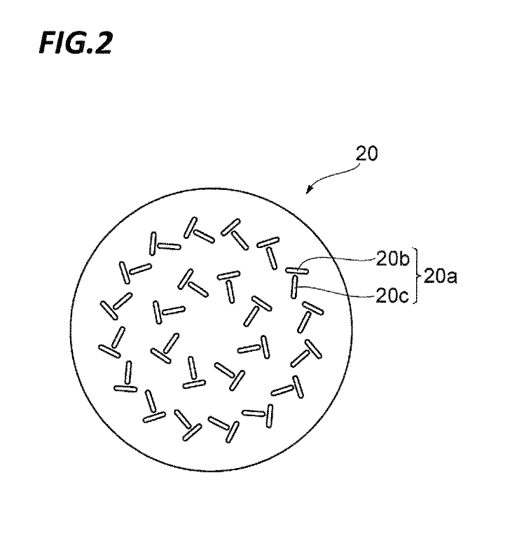

The slot plate 20 is a substantially disc-shaped metal plate including multiple slot pairs formed thereon. FIG. 2 is a plan view illustrating an exemplary slot plate. The slot plate 20 includes multiple slot pairs 20a formed thereon. The multiple slot pairs 20a are provided at predetermined intervals in the radial direction and arranged at predetermined intervals in the circumferential direction. Each slot pair 20a includes two slot holes 20b and 20c. The slot hole 20b and the slot hole 20c extend in the intersecting or orthogonal directions.

The film forming apparatus 10 may further include a coaxial waveguide 24, a microwave generator 26, a tuner 28, a waveguide 30, and a mode converter 32. The microwave generator 32 generates microwaves having a frequency of, for example, 2.45 GHz. The microwave generator 26 is connected to an upper portion of the coaxial waveguide 24 through the tuner 28, the waveguide 30, and the mode converter 32. The coaxial waveguide 24 extends along the axis Z which is its central axis. The coaxial waveguide 24 includes an outer conductor 24a and an inner conductor 24b. The outer conductor 24a has a cylindrical shape extending along the center of the axis Z. The lower end of the outer conductor 24a may be electrically connected to an upper end of the cooling jacket 22 having a conductive surface. The inner conductor 24b is provided inside the outer conductor 24a. The inner conductor 24b has a substantially cylindrical shape extending along the axis Z. The lower end of the inner conductor 24b is connected to the slot plate 20 of the antenna 14.

In the film forming apparatus 10, the microwaves generated by the microwave generator 26 are propagated to the dielectric plate 18 through the coaxial waveguide 24 and given to the dielectric window 16 from the slot holes of the slot plate 20.

The dielectric window 16 is substantially disc-shaped and made of, for example, quartz or alumina. The dielectric window 16 is provided just below the slot plate 20. The dielectric window 16 transmits the microwaves received from the antenna 14 and introduces the microwaves into the plasma generating chamber S1. Thus, an electric field is generated just below the dielectric window 16, and plasma of the noble gas is generated in the plasma generating chamber S1.

Below the first sidewall 12a, the second sidewall 12b extends to be continuous with the first sidewall 12a. The second sidewall 12b has a substantially cylindrical shape extending in the axis Z direction, and defines the processing chamber S2. The film forming apparatus 10 includes a placing table 36 in the processing chamber S2. The placing table 36 may support a workpiece W on its upper surface. In an exemplary embodiment, the placing table 36 is supported by a support 38 that extends from the bottom portion 12c of the processing chamber 12 in the axis Z direction. In an exemplary embodiment, the placing table 36 includes a temperature control mechanism T such as, for example, a heater or a cooler. Further, the placing table 36 may include an attracting and holding mechanism such as, for example, an electrostatic chuck.

In the processing chamber S2, a pipe P21 is provided above the placing table 36 to extend annularly around the axis Z. The pipe P21 is provided with a plurality of injection ports H2 that injects a gas to the processing chamber S2. The pipe P21 is connected with a pipe P22 that penetrates the second sidewall 12b and extends to the outside of the processing container 12. The pipe P22 is connected with a gas source G2 via a valve V21, a mass flow controller M2, and a valve V22. The gas source G2 is a precursor gas source and supplies an aromatic hydrocarbon gas having a methyl group as a precursor gas. The aromatic hydrocarbon gas having a methyl group is, for example, a toluene gas. The gas source G2, the valve V21, the mass flow controller M2, the valve V22, the pipes P21 and P22, and the injection ports H2 constitute a precursor gas supply system. The precursor gas supply system controls the flow rate of the precursor gas from the gas source G2 in the mass flow controller M2, and supplies the precursor gas into the processing chamber S2 at the controlled flow rate. Hereinafter, descriptions will be made on an exemplary embodiment in which a toluene gas is supplied as the precursor gas to the processing chamber S2.

In the film forming apparatus 10, a shielding unit 40 is provided between the plasma generating chamber S1 and the processing chamber S2, and the plasma generating chamber S1 and the processing chamber S2 are separated from each other by the shielding unit 40. The shielding unit 40 is supported by, for example, the first sidewall 12a. The shielding unit 40 is a substantially disc-shaped member. The shielding unit 40 includes a plurality of openings 40h that communicate the plasma generating chamber S1 and the processing chamber S2. In an exemplary embodiment, the shielding unit 40 may be connected to a high-frequency supply 42 so as to impart high-frequency voltage to the shielding unit 40.

The shielding unit 40 has a shielding property against ultraviolet rays generated in the plasma generating chamber S1. That is, the shielding unit 40 may be made of a material that does not transmit the ultraviolet rays. Further, in an exemplary embodiment, when ions generated in the plasma generating chamber S1 pass through the openings 40h while being reflected by an inner wall defining the openings 40h, the shielding unit 40 donates electrons to the ions. Accordingly, the shielding unit 40 neutralizes the ions and discharges the neutralized ions, that is, neutral particles to the processing chamber S2. In an exemplary embodiment, the shielding unit 40 may be made of graphite. In another exemplary embodiment, the shielding unit 40 may be an aluminum member or an aluminum member whose surface is anodized or is formed with an yttria film.

In an exemplary embodiment, the film forming apparatus 10 includes a pressure gauge 44 that measures a pressure in the plasma generating chamber S1 and a pressure gauge 46 that measures a pressure in the processing chamber S2. In the film forming apparatus 10, a pressure adjustor 50 and a vacuum pump 52 are connected to an exhaust pipe 48 that is connected to the processing chamber S2 in the bottom portion 12c. The pressure adjustor 50 and the vacuum pump 52 constitute an exhaust device. In the film forming apparatus 10, based on the pressures measured by the pressure gauges 44 and 46, the flow rate of the noble gas may be adjusted by the mass flow controller M1, the flow rate of the precursor gas may be adjusted by the mass flow controller M21, and the exhaust rate may be adjusted by the pressure adjustor 50. Thus, the film forming apparatus 10 may set the pressure in the plasma generating chamber S1 and the processing chamber S2 at any pressure.

In an exemplary embodiment, the pressure in the plasma generating chamber S1 is adjusted to be 70 Pa or more. In addition, the pressure chamber S2 is adjusted such that the pressure in the plasma generating chamber S1 is twice the pressure in the processing chamber S2 or less, that is, the pressure ratio is 2 or less.

As illustrated in FIG. 1, in an exemplary embodiment, the film forming apparatus 10 further includes a controller Cnt. The controller Cnt may be a controller such as, for example, a programmable computer device. The controller Cnt may control respective parts of the plasma processing apparatus 10 in accordance with a program based on a recipe. For example, the controller Cnt may control the start and stop of the supply of the noble gas by sending a control signal to the valves V11 and V12, and may control the flow rate of the noble gas by sending a control signal to the mass flow controller M1. In addition, the controller Cnt may control the start and stop of the supply of the precursor gas by sending a control signal to the valves V21 and V22, and may control the flow rate of the precursor gas by sending a control signal to the mass flow controller M2. Further, the controller Cnt may control the exhaust rate by sending a control signal to the pressure adjustor 50. Further, the controller Cnt may control the power of the microwaves by sending a control signal to the microwave generator 26, and may control the output voltage of the high-frequency power (RF power) by sending a control signal to the high-frequency power supply 42. Further, the controller Cnt may control the temperature of the placing table 36 by sending a control signal to a temperature control mechanism of the placing table 36.

Hereinafter, a principle of the carbon film formation using the film forming apparatus 10 will be explained, and then, a carbon film formation method according to an exemplary embodiment will be described. In the method, a workpiece W is first placed on the placing table 36. In an exemplary embodiment, the controller Cnt controls the temperature control mechanism of the placing table 36 at that time, so that the temperature of the placing table is adjusted to 100° C. or less. The controller Cnt may cool the placing table to −50° C.

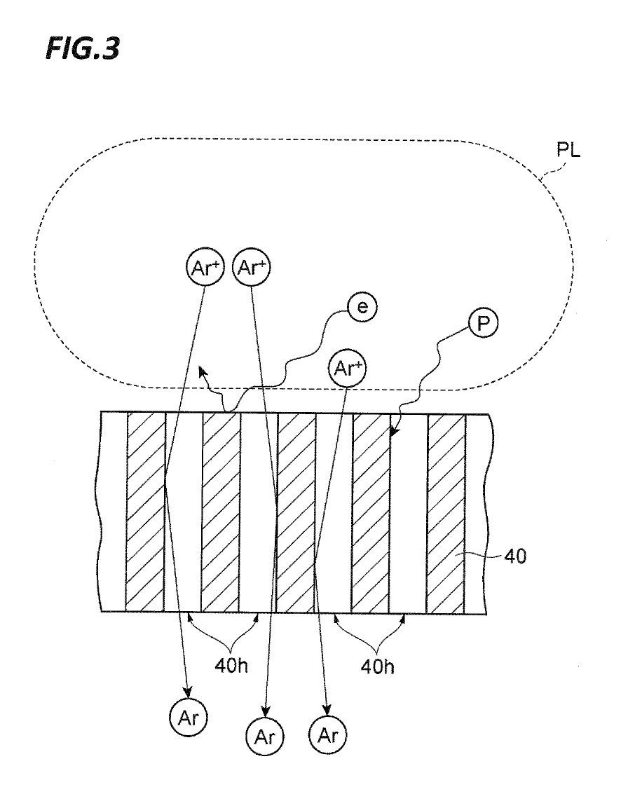

Further, the noble gas is supplied to the plasma generating chamber S1 above the shielding unit 40 and the microwaves are supplied to the plasma generating chamber S1. Accordingly, as illustrated in FIG. 3, plasma PL of the noble gas is generated in the plasma generating chamber S1. FIG. 3 illustrates the plasma PL of argon gas that is the noble gas. In the plasma PL, argon ions, electrons, and photons of ultraviolet rays are generated. In the figure, the argon ions are indicated as “Ar⁺” surrounded by a circle, the electrons are indicated as “e” surrounded by a circle, and the photons are indicated as “P” surrounded by a circle.

In the plasma PL, the electrons are reflected by the shielding unit 40 and returned to the plasma generating chamber S1. Further, the photons are shielded by the shielding unit 40. Meanwhile, the argon ions come into contact with the inner wall defining the openings 40h in the middle of the openings 40h, thereby receiving electrons from the shielding unit 40. Thus, the argon ions are neutralized, and then, discharged as neutral particles to the processing chamber S2. In the figure, the neutral particles of the argon are indicated as “Ar” surrounded by a circle.

Simultaneously, the precursor gas is supplied to the processing chamber S2. At this time, the controller Cnt controls the pressure adjustor 50, so that the exhaust rate is controlled. Accordingly, the plasma generating chamber S1 is adjusted to 70 Pa or more and the pressure in the plasma generating chamber is adjusted to be twice a pressure in the processing chamber S2 or less.

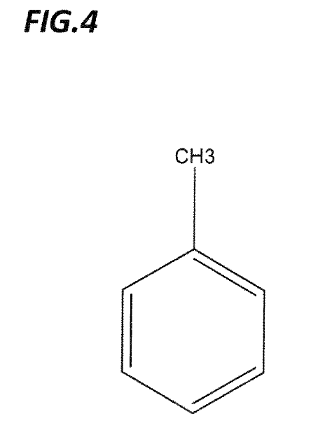

Further, in the processing chamber S2, the argon neutral gas is irradiated to the toluene gas that is the precursor gas. As illustrated in FIG. 4, the toluene is aromatic hydrocarbon having a methyl group, which has alternating carbon-carbon single bonds and double bonds. As described above, in the method, the plasma of the noble gas is excited by the microwaves (e.g., microwaves supplied from a radial line slot antenna in an exemplary embodiment) in the plasma generating chamber S1. Unlike an inductively coupled plasma source, the microwaves supplied from a radial line slot antenna may generate plasma of high density and low electron temperature even in a wide pressure range ranging from a low pressure region to a high pressure region.

When particles of the plasma are irradiated through the shielding unit 40 to the toluene gas that is the precursor gas, the bond between toluene molecules is broken, so that the toluene is dissociated. Here, as described above, when the pressure in the plasma generating chamber is set to 70 Pa or more and the pressure in the plasma generating chamber is set to be twice a pressure in the processing chamber or less, the particles passing through the shielding unit 40 has an energy capable of suppressing the excessive dissociation of the toluene. By these particles, the toluene molecule is cleaved mainly on the methyl group, and radicals derived from the toluene are produced in large amounts. The radical has C═C—C═C* as a carbon skeleton. That is, it is a radical that maintains a part of the molecular structure of the toluene in which single bonds and double bonds are arranged alternately. The radicals produced from the toluene gas are collected on the workpiece W which is cooled by the placing table 36, and radically polymerized on the workpiece W. Accordingly, a carbon film F is produced on the workpiece W.

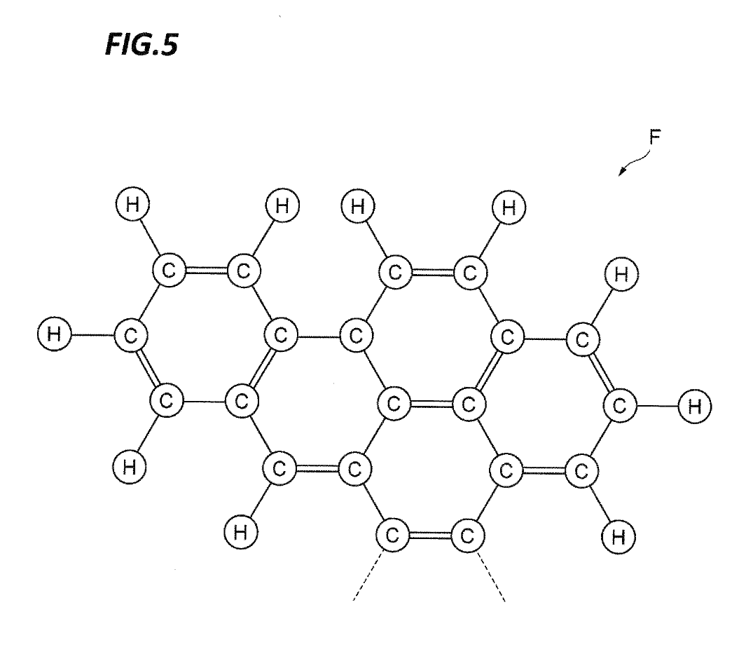

FIG. 5 illustrates an example of the carbon film F formed by the carbon film formation method according to the above-described exemplary embodiment. The carbon film F is polycyclic aromatic hydrocarbon (PAH) having a π-conjugated ring structure. Further, in an exemplary embodiment, the carbon film F may be aromatic hydrocarbon having a π-conjugated chain structure. In the carbon film F having such a structure, carriers are able to migrate through the π-conjugated bond. Accordingly, the carbon film F has a high carrier mobility. Further, since the photons are shielded by the shielding unit 40 during the radical polymerization, the photons are suppressed from being irradiated to the carbon film F in the processing chamber S2. Therefore, since the irradiation of the photons is suppressed when the radicals are polymerized on the workpiece W, a defect causing a carrier trap may be suppressed from occurring in the carbon film. By the principle described above, the carbon film F formed on the workpiece W has a high conductivity.

The method of forming the carbon film F using the film forming apparatus 10 has been described. According to the method, radicals derived from toluene are produced, and the radicals are radically polymerized on the workpiece W to form the carbon film F having a π-conjugated ring structure or a π-conjugated chain structure. Since the carbon film F has a π-conjugated structure, the carbon film has a high carrier mobility and a high conductivity. In the method, the particles are irradiated to cleave toluene, and the radicals are polymerized while maintaining the molecular structure of the toluene to form the carbon film F. Therefore, the carbon film F may be formed at a low temperature.

Hereinafter, descriptions will be made on test examples and comparative examples using the film forming apparatus 10.

First, using the film forming apparatus 10, a carbon film was formed on a workpiece W under conditions of Test Example 1 and Comparative Examples 1 to 6 shown in Table 1 below. In Test Example 1 and Comparative Examples 1 to 6, toluene gas was supplied as a precursor gas to the processing chamber S2, and Ar gas was supplied as a noble gas to the plasma generating chamber S1. Then, the conductivities of the carbon films obtained by Test Example 1 and Comparative Examples 1 to 6 were measured by a four-probe method or a mercury probe method. The conductivities of the carbon films obtained in Test Example 1 and Comparative Examples 1 to 6 are shown in the rightmost column of Table 1.

TABLE 1

| | | | | | | Power of | frequency of | | | | |
|---|---|---|---|---|---|---|---|---|---|---|---|
| | Pressure in | | | | | high- | high- | | | Temper- | |
| | plasma | Pressure in | | | | frequency | frequency | Flow | Flow | ature | |
| | generating | processing | | Power of | Frequency of | power | power | rate of | rate of | of placing | Conduc- |
| | chamber | chamber | Pressure | microwaves | microwaves | supply | supply | toluene | Ar gas | table | tivity |
| | [Pa] | [Pa] | ratio | [kW] | [GHz] | [W] | [W] | [sccm] | [sccm] | [° C.] | [S/cm] |
| Test | 75.0 | 75.0 | 1.0 | 2.5 | 2.45 | 300 | 150 | 30 | 100 | −50 | 11 |
| Ex. 1 | | | | | | | | | | | |
| Comp. | 13.0 | 13.0 | 1.0 | 2.5 | 2.45 | 300 | 150 | 30 | 100 | −50 | 1.4 × 10⁻⁶ |
| Ex. 1 | | | | | | | | | | | |
| Comp. | 7.5 | 5.0 | 1.5 | 2.5 | 2.45 | 300 | 150 | 30 | 100 | −50 | 3 |
| Ex. 2 | | | | | | | | | | | |
| Comp. | 4.0 | 1.3 | 3.0 | 2.5 | 2.45 | 300 | 150 | 30 | 100 | −50 | 1.7 × 10⁻⁴ |
| Ex. 3 | | | | | | | | | | | |
| Comp. | 9.0 | 2.3 | 4.0 | 2.5 | 2.45 | 300 | 150 | 30 | 300 | −50 | 2.4 × 10⁻¹⁶ |
| Ex. 4 | | | | | | | | | | | |
| Comp. | 10.5 | 2.6 | 4.0 | 2.5 | 2.45 | 300 | 150 | 30 | 500 | −50 | 1.9 × 10⁻¹³ |
| Ex. 5 | | | | | | | | | | | |
| Comp. | 11.0 | 4.4 | 2.5 | 2.5 | 2.45 | 300 | 150 | 30 | 500 | −50 | 1.8 × 10⁻⁴ |
| Ex. 6 | | | | | | | | | | | |

As shown in Table 1, it has been found that the carbon film formed in Test Example 1, in which the pressure in the plasma generating chamber S1 was set to 75 Pa and the pressure ratio was set to 1, had an excellent conductivity of 11 S/m. Meanwhile, it has been found that the carbon films formed in Comparative Examples 1 to 6, in which the pressure in the plasma generating chamber was less than 70 Pa, and the pressure ratio was more than 2, had an insufficient conductivity of 3 S/m or less.

Next, using the film forming apparatus 10, Sample 1 was obtained by forming a carbon film on a workpiece W under the same conditions as in Test Example 1. Sample 2 was obtained by forming a carbon film on a workpiece W under the same conditions as in Test Example 1 except that the power of the microwaves from the microwave generator 26 was set to 3.5 kW. Sample 3 was obtained by forming a carbon film on a workpiece W under the same conditions as in Test Example 1 except that the power of the high-frequency power supply 42 was set to 450 W.

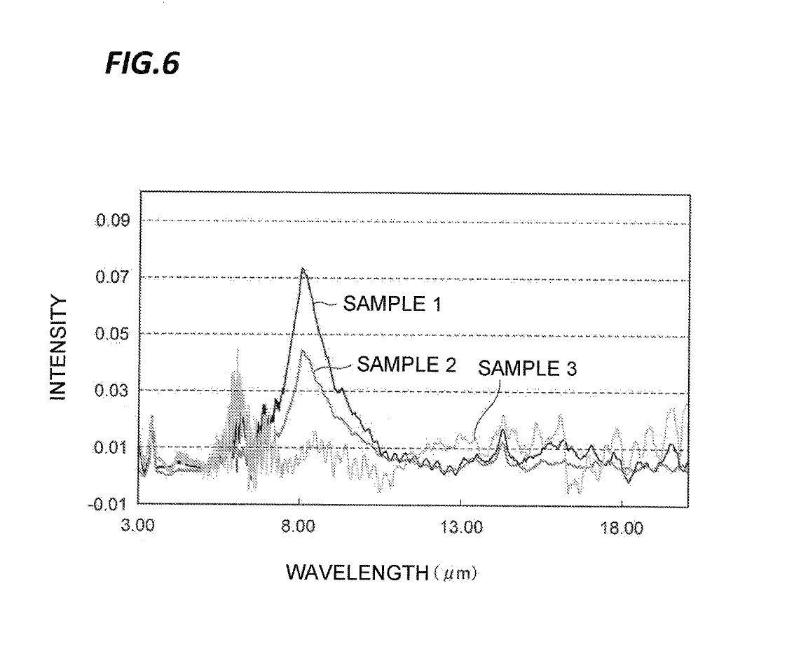

FIG. 6 illustrates an infrared absorption spectra obtained by Fourier transform infrared spectroscopy (FT-IR spectroscopy) for Samples 1 to 3. It is known that polycyclic aromatic hydrocarbon has an absorption peak due to C—C stretching and contracting vibration at a wavelength of 7.7 μm, and an absorption peak due to C—H out-of-plane bending and stretching vibration and an absorption peak due to C—H in-plane bending and stretching vibration at a wavelength of 8.6 μm. As illustrated in FIG. 6, the infrared absorption spectrum for Sample 1 has an absorption peak at a wavelength of 7.7 μm to 8.6 μm. From the result, it has been found that Sample 1 is a carbon film having at least partially polycyclic aromatic hydrocarbon, that is, a π-conjugated ring structure. Meanwhile, the infrared absorption spectra for Sample 2 and Sample 3 have a smaller absorption peak at a wavelength of 7.7 μm to 8.6 μm, as compared with that of Sample 1. In Sample 2 and Sample 3, therefore, it has been found that the π-conjugated ring structure formed in the film is smaller as compared with Sample 1. Since the power of the microwaves from the microwave generator 26 and the power of the high-frequency power supply 42 in the preparation conditions of Samples 2 and 3 are set higher, respectively, as compared with Test Example 1, it is presumed that the energy of the particles passing through the shielding unit 40 becomes higher so that the toluene is excessively dissociated.

Next, the electrode characteristics of Samples 1 to 3 were evaluated by an electrochemical measurement method (cyclic voltammetry). In the cyclic voltammetry, Samples 1 to 3 were used as a working electrode, and a mixture of 2 mM ferrocene methanol solution and 0.1 M KCl solution was used as an electrolyte. Electrode potential was swept at a range of −0.5 V to 1 V, and the sweep rate was set to 100 mV/sec.

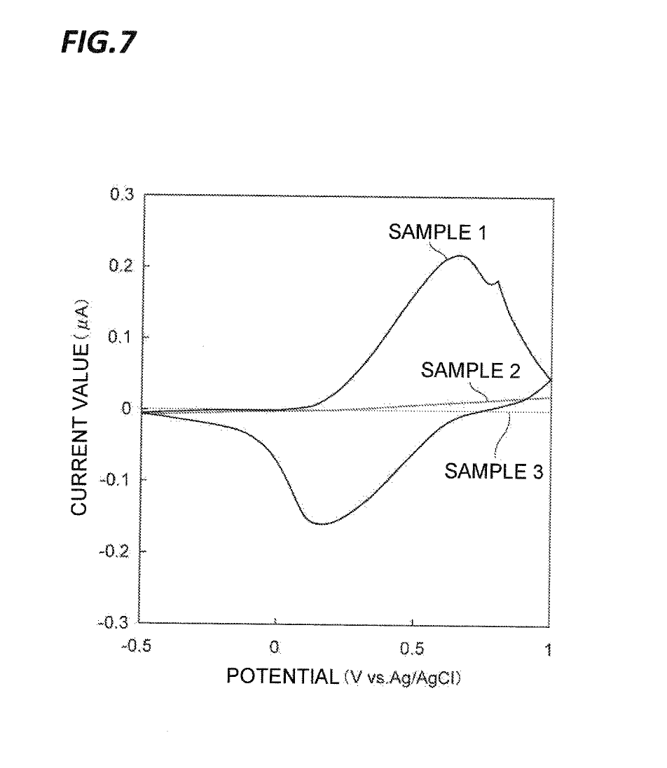

The measurement results of Samples 1 to 3 by the cyclic voltammetry are illustrated in FIG. 7. As illustrated in FIG. 7, it has been found that larger oxidation-reduction current may be obtained in the electrode of Sample 1, as compared with the electrodes of Samples 2 and 3.

The present disclosure has been described in detail based on the exemplary embodiment. However, the present disclosure is not limited to the exemplary embodiment. In the present disclosure, various modifications may be made without departing from the spirit of the present disclosure.

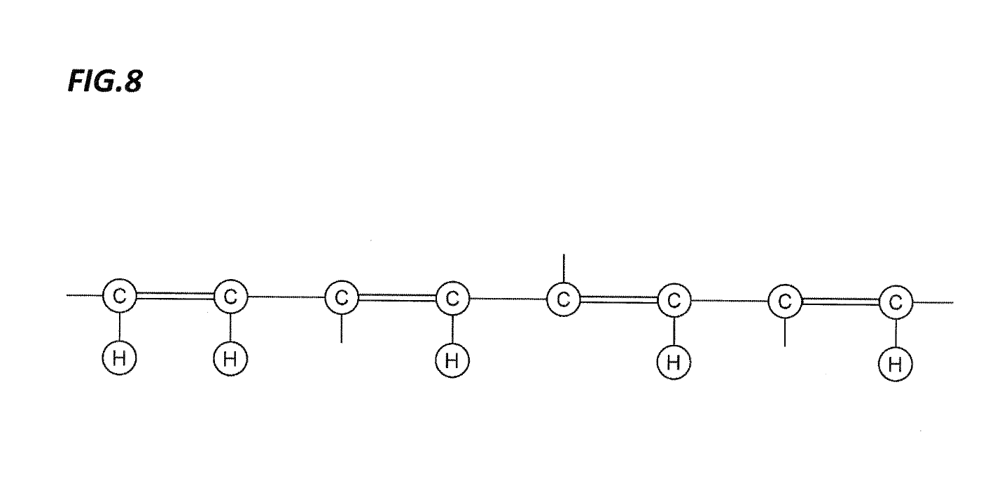

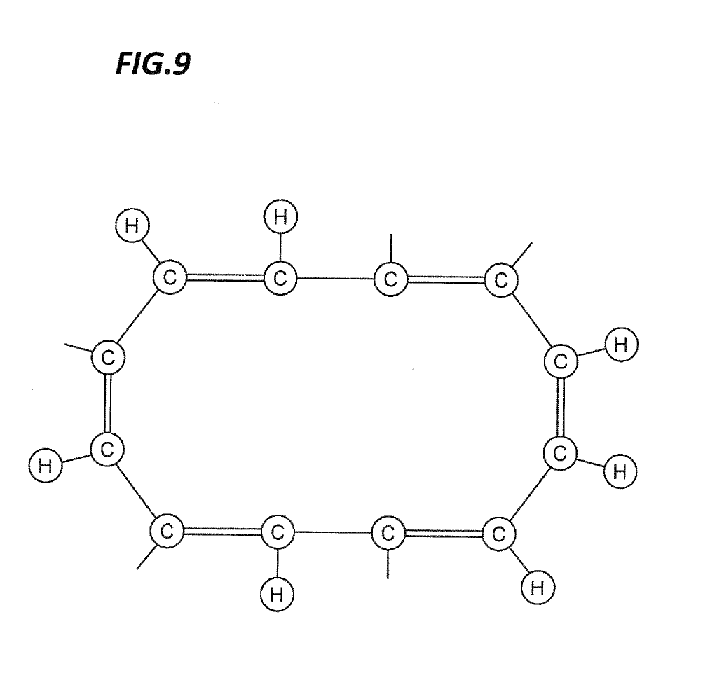

For example, in order to increase the carrier concentration, a dopant may be supplied together with the precursor gas to the processing chamber S2 by the precursor gas supply system. The dopant may be selected from any one of iodine, bromine, nitrogen, and boron. Further, the carbon film F is not limited to the structure illustrated in FIG. 5, and may have any structure, which is a polycyclic aromatic hydrocarbon having a π-conjugated ring structure or an aromatic hydrocarbon having a π-conjugated chain structure. For example, the carbon film F may have a chain structure as illustrated in FIG. 8 or a macro ring structure as illustrated in FIG. 9. Further, the precursor gas supplied to the processing chamber S2 is not limited to toluene as long as it is an aromatic hydrocarbon gas having a methyl group, and example thereof may include dimethyl toluene and trimethyl toluene.

### DESCRIPTION OF SYMBOL

10: film forming apparatus, 12: processing container, 14: antenna, 16: dielectric window, 18: dielectric plate, 20: slot plate, 22: cooling jacket, 24: coaxial waveguide, 26: microwave generator, 28: tuner, 30: waveguide, 32: mode converter, 36: placing table, 38: support, 40: shielding unit, 40h: opening, 42: high-frequency power supply, 44, 46: pressure gauge, 48: exhaust pipe, 50: pressure adjustor, 52: vacuum pump, Cnt: controller, F: carbon film, G1: gas source, G2: gas source, H1: injection port, H2: injection port, M1: mass flow controller, M2: mass flow controller, PL: plasma, S1: plasma generating chamber, S2: processing chamber, T: temperature control mechanism, W: workpiece.

1. A carbon film formation method comprising:
supplying an aromatic hydrocarbon gas having a methyl group into a processing chamber that accommodates a workpiece;
generating plasma of a noble gas in a plasma generating chamber that is isolated from the processing chamber by a shielding unit;
supplying particles in the plasma into the processing chamber through an opening in the shielding unit; and
irradiating the particles to the aromatic hydrocarbon gas to form a carbon film having a π-conjugated ring structure or a π-conjugated chain structure on the workpiece.

2. The carbon film formation method of claim 1, wherein the aromatic hydrocarbon gas is a toluene gas.

3. The carbon film formation method of claim 1, wherein, when the carbon film is formed, a pressure in the plasma generating chamber is set to 70 Pa or more and the pressure in the plasma generating chamber is set to be twice a pressure in the processing chamber or less.

4. The carbon film formation method of claim 1, wherein, when the carbon film is formed, a temperature of a placing table on which the workpiece is placed is set to 100° C. or less.

5. The carbon film formation method of claim 1, wherein the shielding unit has a shielding property against ultraviolet rays.

6. The carbon film formation method of claim 1, wherein the plasma is generated by supplying microwaves into the plasma generating chamber.

7. The carbon film formation method of claim 6, wherein the microwaves are supplied from a radial line slot antenna.

8. The carbon film formation method of claim 1, wherein, when the carbon film is formed, the processing chamber is supplied any one selected from iodine, bromine, nitrogen, and boron as a dopant.

9. (canceled)
